(19) United States
(12) Patent Application Publication
(10) Pub. No.: US 2026/0018366 A1
(43) Pub. Date: Jan. 15, 2026

(54) Workpiece Processing System with Multiple Beam Angles

(71) Applicant: Applied Materials, Inc., Santa Clara, CA (US)

(72) Inventors: Sage Toko Garrett Doshay, Saratoga, CA (US); Joseph C. Olson, Beverly, MA (US)

(21) Appl. No.: 18/768,991

(22) Filed: Jul. 10, 2024

(51) Int. Cl. H01J 37/08; H01J 37/05; H01J 37/20; H01J 37/305; H01L 21/67

(52) U.S. Cl. CPC H01J 37/08; H01J 37/05; H01J 37/20; H01J 37/3053; H01J 2237/20235; H01L 21/67069

(57) ABSTRACT

A workpiece processing system with an ion source that includes two or more extraction apertures, each producing two beamlets at different extraction angles, is disclosed. The ion source includes blockers disposed within the ion source that manipulate the plasma sheath to allow extraction of ions at different extraction angles. The ion source may include at least two blockers, each proximate to a respective extraction aperture. These blockers may be different sizes or have different offsets relative to their respective extraction aperture. These differences result in ion beamlets of different extraction angles being extracted through the different extraction apertures. In another embodiment, the heights of the extraction apertures may differ. The blockers associated with these different sized extraction apertures may be identical, or may differ. Further, in some embodiments, the blockers may be electrically biased at different voltages to produce ion beamlets of different extraction angles.

### FIELD

Embodiments of the present disclosure relate to a workpiece processing system including an ion source with multiple apertures to provide multiple angled beamlets.

### BACKGROUND

Ions are typically directed at workpieces at a zero incident angle, where a zero incident angle represents an angle that is perpendicular to the surface of the workpiece. However, in certain semiconductor manufacturing processes, it is advantageous for the ions to strike the workpiece at a non-zero incident angle. Typically, ions are extracted from an ion source through an extraction aperture. One technique to extract ions at a non-zero incident angle is to install a blocker within the ion source near the extraction aperture. The blocker modifies the plasma sheath within the ion source, such that the ions are extracted at non-zero incident angles.

However, in certain applications, it may be beneficial to be able to implant or etch a workpiece using ion beamlets that are directed at a plurality of angles. To change the angles of a traditional ion source, manual intervention, in the form of hardware modifications, are performed, reducing throughput.

Therefore, it would be beneficial if there were a workpiece processing system that produced at least four beamlets at 2 or more different angles simultaneously.

### SUMMARY

A workpiece processing system with an ion source that includes two or more extraction apertures, each producing two beamlets at different extraction angles, is disclosed. The ion source includes blockers disposed within the ion source that manipulate the plasma sheath to allow extraction of ions at different extraction angles. The ion source may include at least two blockers, each proximate to a respective extraction aperture. These blockers may be different sizes or have different offsets relative to their respective extraction aperture. These differences result in ion beamlets of different extraction angles being extracted through the different extraction apertures. In another embodiment, the heights of the extraction apertures may differ. The blockers associated with these different sized extraction apertures may be identical, or may differ. Further, in some embodiments, the blockers may be electrically biased at different voltages to produce ion beamlets of different extraction angles.

According to one embodiment, a workpiece processing system is disclosed. The workpiece processing system comprises a workpiece holder; and an ion source chamber, comprising: a plasma source; a plurality of chamber walls; an extraction plate with a first extraction aperture and a second extraction aperture; a first blocker disposed within the ion source chamber and proximate the first extraction aperture; and a second blocker disposed within the ion source chamber and proximate the second extraction aperture; wherein each blocker modifies a plasma sheath inside the ion source chamber proximate its respective extraction aperture so as to create two beamlets exiting from its respective extraction aperture, each beamlet having an extraction angle; and wherein the first blocker and second blocker have different sizes such that beamlets extracted from the first extraction aperture and second extraction aperture have different extraction angles. In some embodiments, each of the beamlets has a different extraction angle. In some embodiments, the workpiece holder is scanned in a height direction. In certain embodiments, the first blocker and the second blocker have different sizes in the height direction. In certain embodiments, the first extraction aperture and the second extraction aperture have a same dimension in the height direction. In certain embodiments, the first extraction aperture and the second extraction aperture have different dimensions in the height direction.

According to another embodiment, a workpiece processing system is disclosed. The workpiece processing system comprises a workpiece holder; and an ion source chamber, comprising: a plasma source; a plurality of chamber walls; an extraction plate with a first extraction aperture and a second extraction aperture; a first blocker disposed within the ion source chamber and proximate the first extraction aperture; and a second blocker disposed within the ion source chamber and proximate the second extraction aperture; wherein each blocker modifies a plasma sheath inside the ion source chamber proximate its respective extraction aperture so as to create two beamlets exiting from its respective extraction aperture, each beamlet having an extraction angle; and wherein the first blocker is positioned differently relative to the first extraction aperture than the second blocker is positioned relative to the second extraction aperture such that beamlets extracted from the first extraction aperture and second extraction aperture have different extraction angles. In some embodiments, each of the beamlets has a different extraction angle. In some embodiments, the workpiece holder is scanned in a height direction. In certain embodiments, the first blocker is centered in the height direction relative to the first extraction aperture and the second blocker is not centered in the height direction relative to the second extraction aperture. In certain embodiments, a distance from the first blocker to the extraction plate is different from a distance from the second blocker to the extraction plate. In certain embodiments, the first extraction aperture and the second extraction aperture have a same dimension in the height direction. In certain embodiments, the first extraction aperture and the second extraction aperture have different dimensions in the height direction.

According to another embodiment, a workpiece processing system is disclosed. The workpiece processing system comprises a workpiece holder; and an ion source chamber, comprising: a plasma source; a plurality of chamber walls; an extraction plate with a first extraction aperture and a second extraction aperture; a first blocker disposed within the ion source chamber and proximate the first extraction aperture; and a second blocker disposed within the ion source chamber and proximate the second extraction aperture; wherein each blocker modifies a plasma sheath inside the ion source chamber proximate its respective extraction aperture so as to create two beamlets exiting from its respective extraction aperture, each beamlet having an extraction angle; and wherein the first blocker and the second blocker are electrically biased at different voltages such that beamlets extracted from the first extraction aperture and second extraction aperture have different extraction angles. In some embodiments, each of the beamlets has a different extraction angle. In some embodiments, each blocker is in electrical communication with a respective blocker bias power supply. In some embodiments, the first blocker is in electrical communication with a blocker bias power supply and the second blocker is electrically grounded. In some embodiments, the first blocker is electrically floating and the second blocker is biased to a voltage. In certain embodiments, the second blocker is in electrical communication with a blocker bias power supply. In certain embodiments, the second blocker is electrically grounded. In some embodiments, a voltage applied to at least the first blocker is varied over time.

### BRIEF DESCRIPTION OF THE FIGURES

For a better understanding of the present disclosure, reference is made to the accompanying drawings, which are incorporated herein by reference and in which:

FIG. 1 is a view of a workpiece processing system including an ion source that may be used to extract four ion beamlets at different extraction angles according to one embodiment;

FIG. 2 is a view of a workpiece processing system including an ion source that may be used to extract four ion beamlets at different extraction angles according to a second embodiment;

FIG. 3 is a view of a workpiece processing system including an ion source that may be used to extract four ion beamlets at different extraction angles according to a third embodiment;

FIG. 4 is a view of a workpiece processing system including an ion source that may be used to extract four ion beamlets at different extraction angles according to a fourth embodiment; and

FIG. 5 is a view of a workpiece processing system including an ion source that may be used to extract four ion beamlets at different extraction angles according to a fifth embodiment.

### DETAILED DESCRIPTION

As described above, blockers may be disposed within an ion source chamber to cause the ions to be extracted at non-zero extraction angles. In this disclosure, a zero-degree extraction angle is defined as an ion beam that is perpendicular to the surface of the extraction plate. Through the use of multiple extraction apertures and blockers, it is possible to create four or more ion beamlets, having a plurality of different extraction angles.

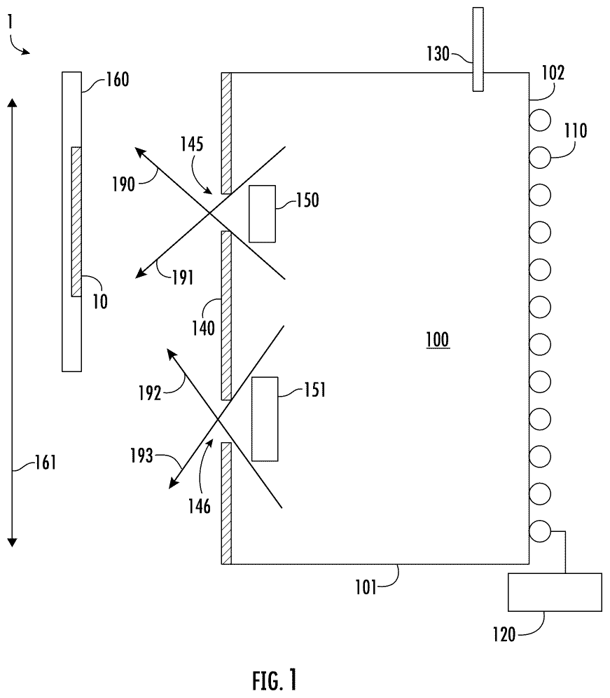

FIG. 1 shows a first embodiment of a workpiece processing system 1 that generates four ion beamlets at different extraction angles. The workpiece processing system 1 includes an ion source chamber 100, comprising a plurality of chamber walls 101. In certain embodiments, one or more of these chamber walls 101 may be constructed of a dielectric material, such as quartz. An RF antenna 110 may be disposed on an exterior surface of a first dielectric wall 102. The RF antenna 110 may be powered by a RF power supply 120. The energy delivered to the RF antenna 110 is radiated within the ion source chamber 100 to ionize a feed gas, which is introduced via gas inlet 130. In other embodiments, the gas is ionized in a different manner, such as through the use of an indirectly heated cathode (IHC), a capacitively coupled plasma source, an inductively coupled plasma source, a Bernas source or any other plasma generator.

One chamber wall, referred to as the extraction plate 140 includes a first extraction aperture 145 and a second extraction aperture 146 through which ions may exit the ion source chamber 100. The extraction plate 140 may be constructed of an electrically conductive material, such as titanium, tantalum or another metal. The extraction plate 140 may be in excess of 300 millimeters in width. Further, the first extraction aperture 145 and second extraction aperture 146 may each be wider than the diameter of the workpiece 10. In certain embodiments, the extraction plate 140 may be coated with a ceramic material. The ceramic material may be yttria, alumina, silica, or any other suitable material. The front surface of the extraction plate 140 may be flat. Throughout this disclosure, the front surface of the extraction plate 140 refers to the surface that faces away from the ion source chamber 100. The rear surface of the extraction plate 140 is the surface that is disposed within the ion source chamber 100.

Disposed within the ion source chamber 100 may be a first blocker 150 and a second blocker 151. Each is located proximate to its respective extraction aperture in the extraction plate 140. The blockers may be a dielectric material that is used to affect the plasma sheath in the vicinity of the respective extraction apertures. In other embodiments, the blockers may be a metal coated with a dielectric material, such as a ceramic material.

The size and placement of each blocker relative to its respective extraction aperture are among the parameters that determine the extraction angle at which the ions exit the respective extraction aperture. In certain embodiments, ions may be extracted at two different extraction angles, such as is shown in FIG. 1. In this embodiment, a first beamlet 190 and a second beamlet 191 are extracted from the first extraction aperture 145 and directed toward the workpiece 10, while a third beamlet 192 and a fourth beamlet 193 are extracted from the second extraction aperture 146 and directed toward the workpiece 10. This may be referred to as a bimodal distribution of extraction angles.

Note that the beamlets have a range of extraction angles. Thus, while the extraction angle of a particular beamlet is described as having a specific value, such as +ααor −α, it is understood that this value represents the center angle of the respective beamlet. Thus, each beamlet contains a range of extraction angles, surrounding a center angle. Further, the current of the beamlet is typically greatest at the center angle.

A platen 160 is disposed outside the ion source chamber 100 proximate the extraction plate 140. The workpiece 10 is disposed on the platen 160. The platen 160 may be scanned in a scanning direction 161 such that the entirety of the workpiece 10 is exposed to the four beamlets. The platen 160 may be electrically biased so as to attract the ions from within the ion source chamber 100 toward the workpiece 10.

The extraction apertures are configured to each have a width, which is the direction perpendicular to the scanning direction 161, that is wider than the workpiece 10 such that the four beamlets strike the entire workpiece during one scanning pass of the workpiece. In this embodiment, the height, which is the direction parallel to the scanning direction 161, may be the same for all extraction apertures.

In the embodiment shown in FIG. 1, the blockers are both centered about the respective extraction aperture, such that the first beamlet 190 and the second beamlet 191 are the same extraction angle, but in opposite directions. For example, these two beamlets may have extraction angles of +α and −α. However, the two blockers are of different heights. This difference in height causes the extraction angles of the third beamlet 192 and the fourth beamlet 193 to be −β and +β, where β is different from α. In some embodiments, the thickness of the two blockers may differ.

Thus, in this embodiment, the ion source chamber 100 has multiple extraction apertures, all having the same height and width. Differently sized blockers are disposed within the ion source chamber 100, each proximate a respective extraction aperture. These differently sized blockers cause the extraction of at least four beamlets, where each has a different extraction angle. These blockers may be different in the height direction.

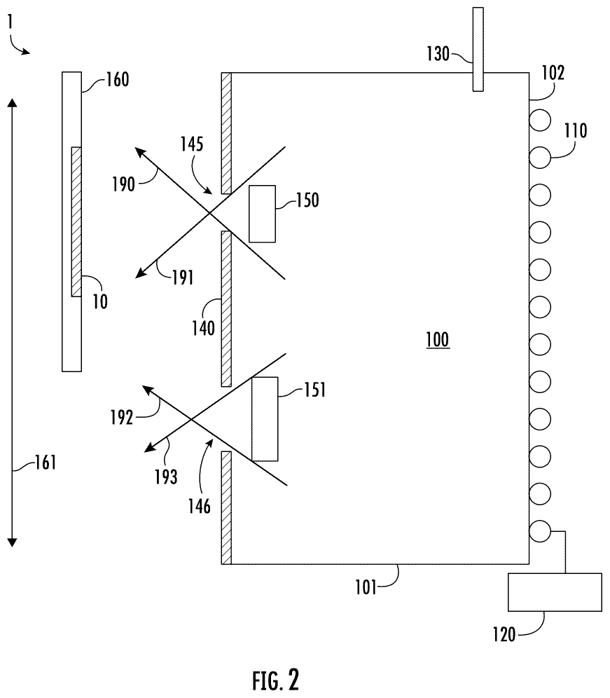

However, in other embodiments, the extraction apertures may have different heights. FIG. 2 shows a system similar to that shown in FIG. 1, wherein the height of the first extraction aperture 145 is different from the height of the second extraction aperture 146. Thus, in certain embodiments, the ion source chamber 100 includes multiple extraction apertures, each having a different height, and an equal number of blockers, each blocker optionally having a different height. In other words, the blockers may be the same height, or may be different heights. This configuration also creates four extraction angles, which may be referred to as +α, −α, −β and +β.

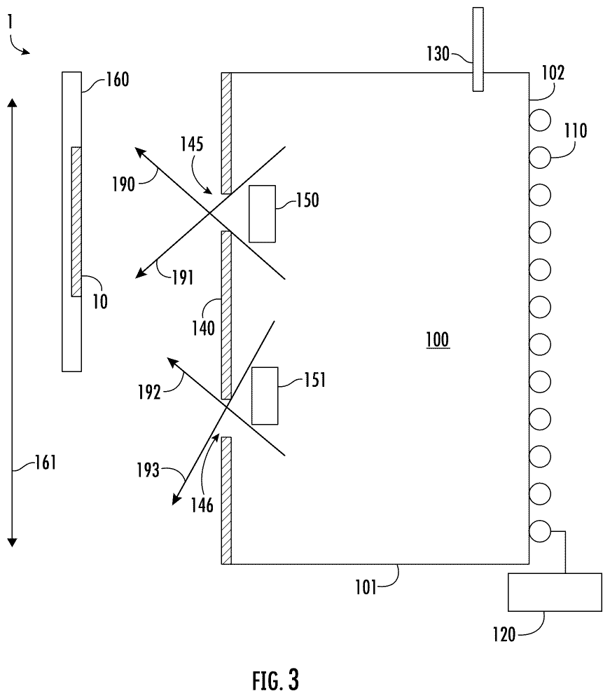

FIG. 3 shows another embodiment where the first blocker 150 is the same height as the second blocker 151, but their position relative to their respective extraction apertures is different. In this figure, the first blocker 150 is centered with respect to the first extraction aperture 145. However, the second blocker 151 is offset in the height direction relative to the second extraction aperture 146. Thus, the extraction angles for the first beamlet 190 and the second beamlet 191 are +α, and −α, respectively. However, the extraction angles for the third beamlet 192 and the fourth beamlet 193 are not symmetric, and may be referred to as +β and −γ.

Further, while FIG. 3 shows the first extraction aperture 145 having the same height as the second extraction aperture 146, it is understood that the heights of these extraction apertures may differ. Similarly, while the blockers are shown having the same height, it is understood that the heights of the blockers may differ as well.

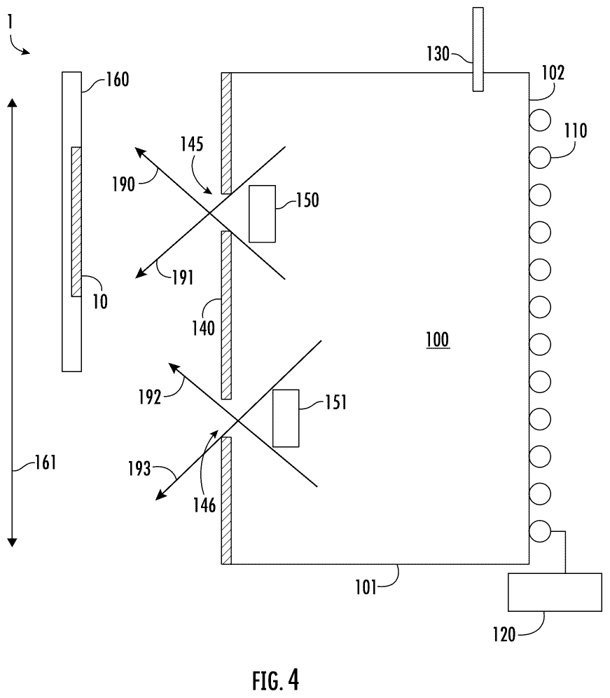

While FIG. 3 shows the blockers offset in the height direction, there are other embodiments where the blockers, which may be the same height or different heights, are offset in a different direction. FIG. 4 shows the blockers positioned at different distances from the interior surface of the extraction plate 140. This distance may be referred to as the gap between the blocker and the extraction plate 140. Thus, the extraction angles may be varied by positioning the blocker at different positions relative to their respective extraction apertures. This difference in position may be in the height direction or a difference in the gap.

As noted above, in certain embodiments, the blockers may be a metal coated with a dielectric material. This configuration allows an electrical bias to be applied to some or all of the blockers.

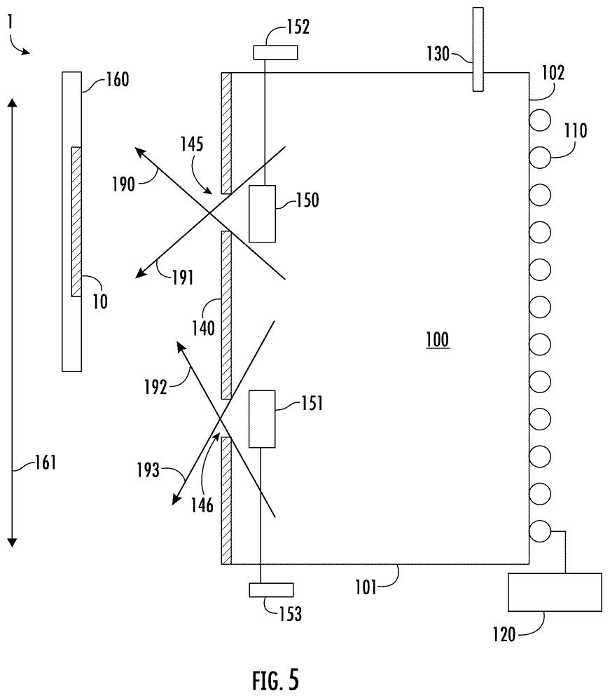

FIG. 5 shows a workpiece processing system 1 wherein the blockers are electrically biased. The first blocker 150 is electrically biased using first blocker bias power supply 152, while the second blocker 151 is electrically biased using second blocker bias power supply 153.

In this embodiment, the voltages applied to the blockers by the power supplies are different. This difference in bias voltage affects the plasma sheath in the vicinity of the extraction apertures, resulting in beamlets having different extraction angles. Further, in certain embodiments, the bias voltages applied to one or both blockers may be variable, such that the bias voltage may be changed after a predetermined interval. For example, one set of bias voltages may be used for N scanning passes, where N is an integer greater than 0. A second set of bias voltages may then be applied to the blockers to create different extraction angles. This allows the time multiplexing of different extraction angles without any other changes to the process conditions or ion source. In certain embodiments, at least one of the blockers is in electrical communication with a variable voltage.

Note that in certain embodiments, one of these power supplies may be omitted if the corresponding blocker is either electrically grounded or electrically floating.

This allows a plurality of different configurations, including:
Two blockers electrically biased at different voltages
One blocker electrically biased at a first voltage; with the second blocker grounded
One blocker electrically biased at a first voltage; with the second blocker electrically floating; or
One blocker electrically floating; with the second blocker grounded.

Additionally, one blocker may be a dielectric material, while the other blocker is a metal coated with a dielectric material. In this embodiment, the blocker made of the dielectric material does not include an associated blocker bias power supply.

Thus, various parameters associated with the blockers may be modified to change the extraction angles of the beamlets exiting the extraction aperture. These parameters include the size of the blocker in the height direction, the position of the blocker in the ion source chamber relative to the extraction aperture in the height direction, the distance between the blocker in the ion source chamber and the extraction plate, and the electrical bias of the blocker. Note that these parameters may be used individually or may be combined in any combination to achieve the desired extraction angles.

While FIGS. 3-5 show the extraction apertures as having the same height, in certain embodiments, the extraction apertures may have different heights.

Further, while the figures show two extraction apertures with two blockers, it is understood that additional extraction apertures may be incorporated in the extraction plate, if desired. Thus, the ion source is not limited to two extraction apertures. Generally, the ion source chamber may include N extraction apertures, where N is an integer greater than 1, and N corresponding blockers. This configuration results in the extraction of 2N beamlets of varying angles.

The system and method described herein have many advantages. There are situations where it may be advantageous to direct ions at a plurality of extraction angles toward a workpiece. For example, when etching, it may be beneficial to target sidewalls of a feature (or of photoresist) at a plurality of angles to achieve a desired result. The present ion source allows the workpiece to be processed by four or more beamlets, each having a unique center angle of extraction. This may be performed without any modification to the ion source, allowing higher throughput.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A workpiece processing system, comprising:
a workpiece holder; and
an ion source chamber, comprising:
a plasma source;
a plurality of chamber walls;
an extraction plate with a first extraction aperture and a second extraction aperture;
a first blocker disposed within the ion source chamber and proximate the first extraction aperture; and
a second blocker disposed within the ion source chamber and proximate the second extraction aperture;
wherein each blocker modifies a plasma sheath inside the ion source chamber proximate its respective extraction aperture so as to create two beamlets exiting from its respective extraction aperture, each beamlet having an extraction angle;
and wherein the first blocker and second blocker have different sizes such that beamlets extracted from the first extraction aperture and second extraction aperture have different extraction angles.

2. The workpiece processing system of claim 1, wherein each of the beamlets has a different extraction angle.

3. The workpiece processing system of claim 1, wherein the workpiece holder is scanned in a height direction.

4. The workpiece processing system of claim 3, wherein the first blocker and the second blocker have different sizes in the height direction.

5. The workpiece processing system of claim 3, wherein the first extraction aperture and the second extraction aperture have a same dimension in the height direction.

6. The workpiece processing system of claim 3, wherein the first extraction aperture and the second extraction aperture have different dimensions in the height direction.

7. A workpiece processing system, comprising:
a workpiece holder; and
an ion source chamber, comprising:
a plasma source;
a plurality of chamber walls;
an extraction plate with a first extraction aperture and a second extraction aperture;
a first blocker disposed within the ion source chamber and proximate the first extraction aperture; and
a second blocker disposed within the ion source chamber and proximate the second extraction aperture;
wherein each blocker modifies a plasma sheath inside the ion source chamber proximate its respective extraction aperture so as to create two beamlets exiting from its respective extraction aperture, each beamlet having an extraction angle;
and wherein the first blocker is positioned differently relative to the first extraction aperture than the second blocker is positioned relative to the second extraction aperture such that beamlets extracted from the first extraction aperture and second extraction aperture have different extraction angles.

8. The workpiece processing system of claim 7, wherein each of the beamlets has a different extraction angle.

9. The workpiece processing system of claim 7, wherein the workpiece holder is scanned in a height direction.

10. The workpiece processing system of claim 9, wherein the first blocker is centered in the height direction relative to the first extraction aperture and the second blocker is not centered in the height direction relative to the second extraction aperture.

11. The workpiece processing system of claim 9, wherein a distance from the first blocker to the extraction plate is different from a distance from the second blocker to the extraction plate.

12. The workpiece processing system of claim 9, wherein the first extraction aperture and the second extraction aperture have a same dimension in the height direction.

13. The workpiece processing system of claim 9, wherein the first extraction aperture and the second extraction aperture have different dimensions in the height direction.

14. A workpiece processing system, comprising:
a workpiece holder; and
an ion source chamber, comprising:
a plasma source;
a plurality of chamber walls;
an extraction plate with a first extraction aperture and a second extraction aperture;
a first blocker disposed within the ion source chamber and proximate the first extraction aperture; and
a second blocker disposed within the ion source chamber and proximate the second extraction aperture;
wherein each blocker modifies a plasma sheath inside the ion source chamber proximate its respective extraction aperture so as to create two beamlets exiting from its respective extraction aperture, each beamlet having an extraction angle;
and wherein the first blocker and the second blocker are electrically biased at different voltages such that beamlets extracted from the first extraction aperture and second extraction aperture have different extraction angles.

15. The workpiece processing system of claim 14, wherein each blocker is in electrical communication with a respective blocker bias power supply.

16. The workpiece processing system of claim 14, wherein the first blocker is in electrical communication with a blocker bias power supply and the second blocker is electrically grounded.

17. The workpiece processing system of claim 14, wherein the first blocker is electrically floating and the second blocker is biased to a voltage.

18. The workpiece processing system of claim 17, wherein the second blocker is in electrical communication with a blocker bias power supply.

19. The workpiece processing system of claim 17, wherein the second blocker is electrically grounded.

20. The workpiece processing system of claim 14, wherein a voltage applied to at least the first blocker is varied over time.
